(19) United States
(12) Patent Application Publication
(10) Pub. No.: US 2022/0278657 A1
(43) Pub. Date: Sep. 1, 2022

(54) POWER AMPLIFIER

(71) Applicant: HITACHI KOKUSAI ELECTRIC INC., Tokyo (JP)

(72) Inventor: Yusaburo GOTO, TOKYO (JP)

(73) Assignee: HITACHI KOKUSAI ELECTRIC INC., Tokyo (JP)

(21) Appl. No.: 17/636,409

(22) PCT Filed: Sep. 25, 2019
(86) PCT No.: PCT/JP2019/037511

§ 371 Date: Feb. 18, 2022

(51) Int. Cl. H03F 3/21; H03F 1/02; H03G 3/30

(52) U.S. Cl. CPC H03F 3/211; H03F 1/0205; H03G 3/3042; H03F 2200/451

(57) ABSTRACT

In order to operate a power amplifier for synthesizing a plurality of amplifier circuits with high efficiency, the gate voltages of the field-effect transistors (FETs) of the plurality of amplifier circuits are adjusted according to an individual difference in saturated power between the amplifier circuits. Specifically, the output ratios of the amplifier circuits (AMP-4, 8) with low saturated power are reduced, whereas the output ratios of the amplifier circuits (AMP-2, 6) with high saturated power are increased. Thus, a device is operated with high efficiency.

### TECHNICAL FIELD

The present invention relates to a power amplifier, and particularly, to a technology of improving the efficiency of a power amplifier.

### BACKGROUND

Recently, an output power level required for a power amplifier is increasing, and when required power is high, a plurality of amplifier circuits (AMPS) are combined to obtain the required power. For example, a high output power amplifier, in which eight AMPS are combined, needs to be operated with high output power and high efficiency, and in order to obtain high efficiency, the AMPS use field-effect transistors (FETs) such as metal-oxide-semiconductor (MOS)-FETs and perform Class B operation with output power levels around saturated power. The performance of the MOS-FETs used in the AMPS has individual differences, and the eight AMPS may have deviations in gain and efficiency. In addition, when the AMPS are included in a device, individual differences in power consumption may occur between the AMPS. Due to the individual differences between the AMPS, it is difficult to operate the device, which combines the output power of the plurality of AMPS, with high output power and high efficiency.

As the related art of the technology, for example, there is Patent Document 1. In Patent Document 1, a power amplifier capable of improving power conversion efficiency when amplifying a signal having a high ratio of peak power to average power is disclosed.

### PRIOR ART DOCUMENTS

### Patent Documents

Patent Document 1: Japanese Laid-open Patent Publication No. 2013-110487

### SUMMARY

### Problems to Be Resolved by the Invention

As described above, when the output power of a plurality of AMPS is combined so that the plurality of AMPS operates with high output power and high efficiency, it is necessary to appropriately respond to individual differences existing between the plurality of AMPS.

The present invention is directed to providing a power amplifier which combines the output power of a plurality of AMPS and is capable of operating with high output power and high efficiency.

### Means for Solving the Problem

In order to achieve the objectives, the present invention provides a power amplifier, which combines output power of a plurality of amplifier circuits (AMPs), for controlling output power ratios of the plurality of amplifier circuits on the basis of individual differences in saturated power between the plurality of amplifier circuits.

### Effect of the Invention

According to the present invention, a power amplifier, which combines the output power of a plurality of AMPS, can improve the efficiency of a device.

### BRIEF DESCRIPTION OF THE DRAWINGS

FIG. 1 is a block diagram illustrating one example structure of a high output power amplifier in which eight AMPS are combined.

FIG. 2 is a set of graphs showing a gain and efficiency of each of eight AMPS.

FIG. 3 is a set of graphs showing a comparison of characteristics between AMPS having low current consumption and AMPS having high current consumption.

FIGS. 4A to 4C are graphs for describing the characteristics of a Class B AMP and a factor estimated to reduce the efficiency of the AMP.

FIG. 5 is a graph for describing an adjustment content of a power amplifier according to a first embodiment.

FIG. 6 is a set of graphs showing characteristics when a gate voltage (Vg) of a Class B AMP according to the first embodiment is changed.

### DETAILED DESCRIPTION

Hereinafter, although embodiments for implementing the present invention will be described with reference to the accompanying drawings, the objectives of the present invention will be described first using tables for the sake of more desirable understanding of the present invention.

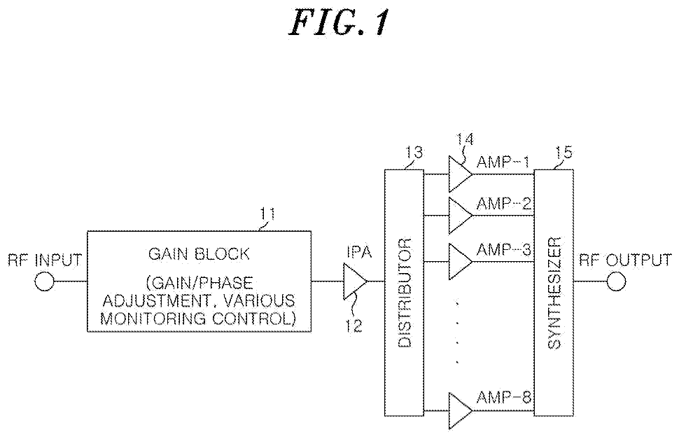

FIG. 1 is a block diagram illustrating one example structure of a high output power amplifier in which eight AMPS are combined. A radio frequency (RF) input is subjected to gain/phase adjustment, various monitoring and control in a gain block 11, and passes through an intermediate power AMP (IPA) 12 which is an AMP in front of a final AMP, is distributed to eight AMPS 14 (AMP-1 to AMP-8) by a distributor 13, is amplified by each of the AMPS 14, is combined by a synthesizer 15, and becomes an RF output.

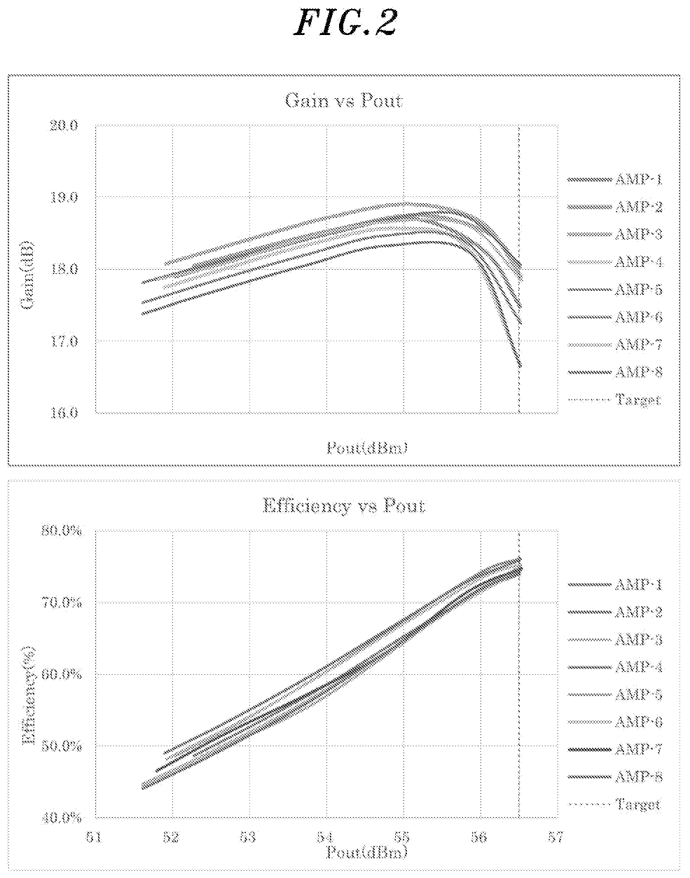

FIG. 2 is a graph showing the performance of each of metal-oxide-semiconductor field-effect transistors (MOS-FETs) of eight AMPS used in the power amplifier of FIG. 1. In FIG. 2, horizontal axes of upper and lower graphs represent output power Pout (dBm) of the AMP, a vertical axis of the upper graph represents a gain (dB) of the AMP, and a vertical axis of the lower graph represents efficiency (%) of the AMP. In addition, ‘Target’ represents the target output power of the AMP. As shown in FIG. 2, there are individual differences in performance between eight MOS-FETs. That is, it is clear that there are deviations in gain and efficiency between the eight AMPS.

In Table 1, device efficiency and current consumption of the AMPS are shown when the power amplifier is operated with regulated output power.

TABLE 1

| | | | | | | | | | Current |
|---|---|---|---|---|---|---|---|---|---|
| Device | | | | | | | | | Consumption |
| Efficiency | AMP-1 | AMP-2 | AMP-3 | AMP-4 | AMP-5 | AMP-6 | AMP-7 | AMP-8 | (Sum) |
| (%) | (A) | (A) | (A) | (A) | (A) | (A) | (A) | (A) | (A) |
| 60.7 | 15.3 | 14.4 | 14.5 | 16.2 | 15.2 | 14.1 | 14.7 | 16.8 | 121.3 |

As shown in Table 1, like the individual differences in performance between the individual AMPS as shown in FIG. 2, there are also individual differences in current consumption (A) between the AMPS. Particularly, values of the current consumption of the AMP-4 and the AMP-8 are greater than those of the remaining AMPS, and current consumptions of the AMP-2 and the AMP-6 are smaller than those of the remaining AMPS. Therefore, the characteristics of four AMPS (AMP-2, AMP-4, AMP-6, and AMP-8) are compared.

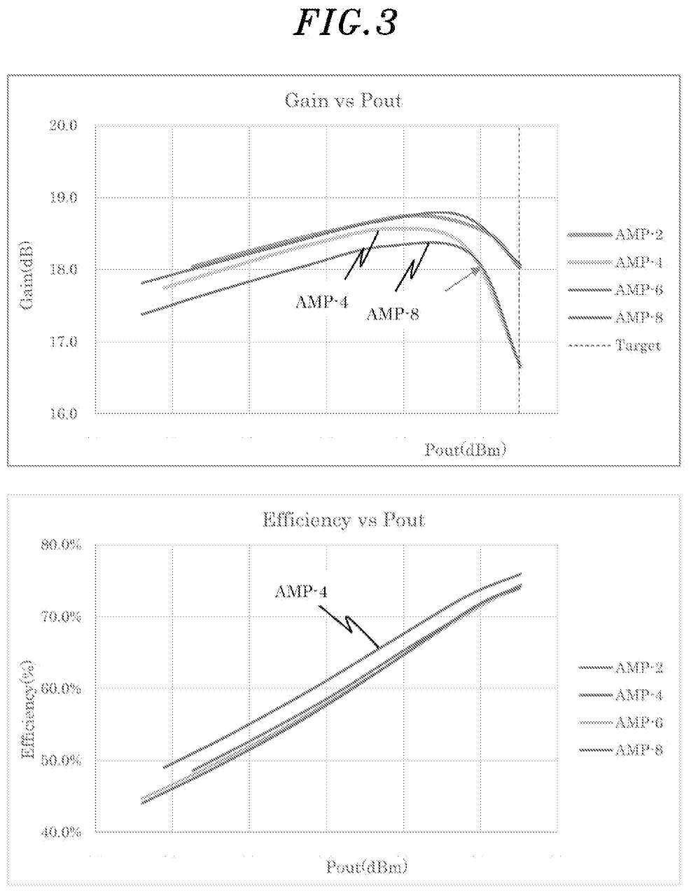

FIG. 3 shows data of the comparison. A horizontal axis, a vertical axis, an upper graph, and a lower graph of FIG. 3 are the same as those of FIG. 2. As shown in FIG. 3, it can be seen that the AMP-4 and the AMP-8 having high current consumption values have gains (dB), which decrease sharply around the target output power as indicated by an arrow of the upper graph, when compared to the AMP-2 and the AMP-6 having low current consumption values. This shows that each of the AMP-4 and the AMP-8 has low saturated (peak) power when compared to the AMP-2 and the AMP-6.

Meanwhile, in efficiency (%) shown in the lower graph, it can be seen that the AMPS have almost the same efficiency except the AMP-4 and the performance efficiency of the AMP-4, which has a high current consumption when included in the device, is the best.

Based on the above consideration of the present inventor, it can be seen that a magnitude of saturated power of the individual AMP affects current consumption when the AMP is included in the device rather than efficiency of the individual AMP.

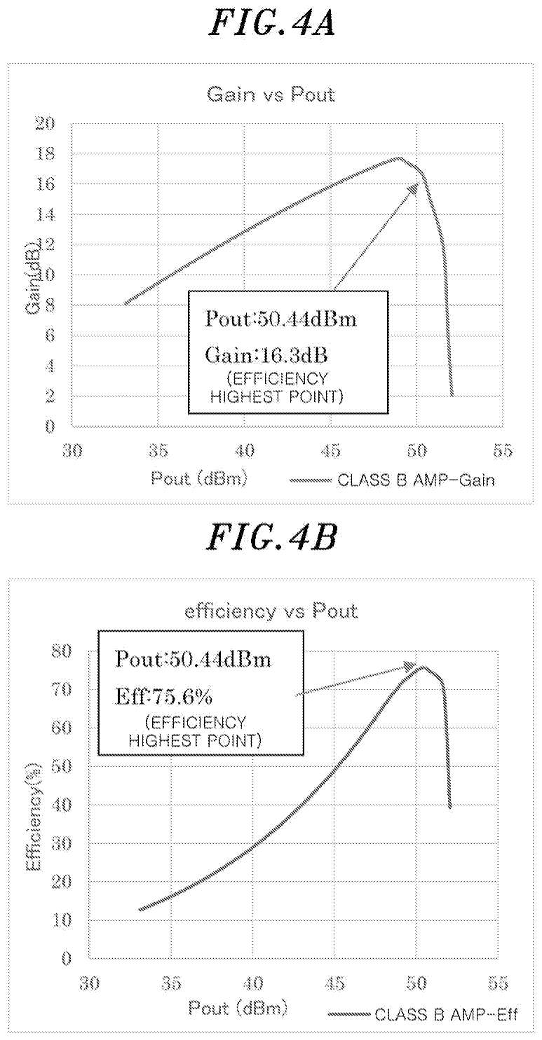

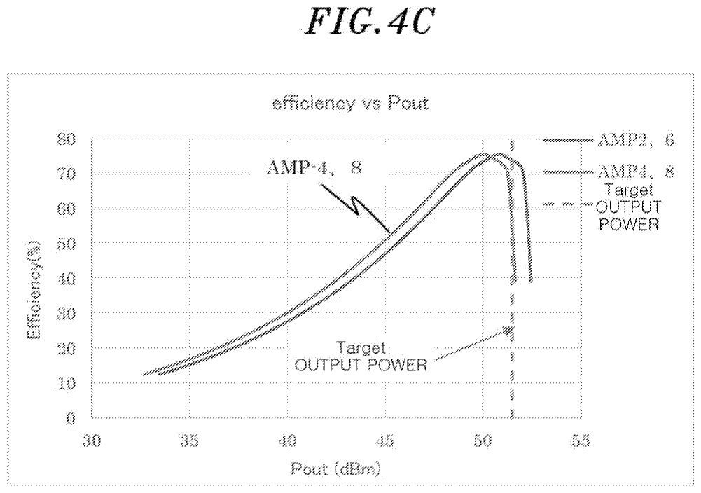

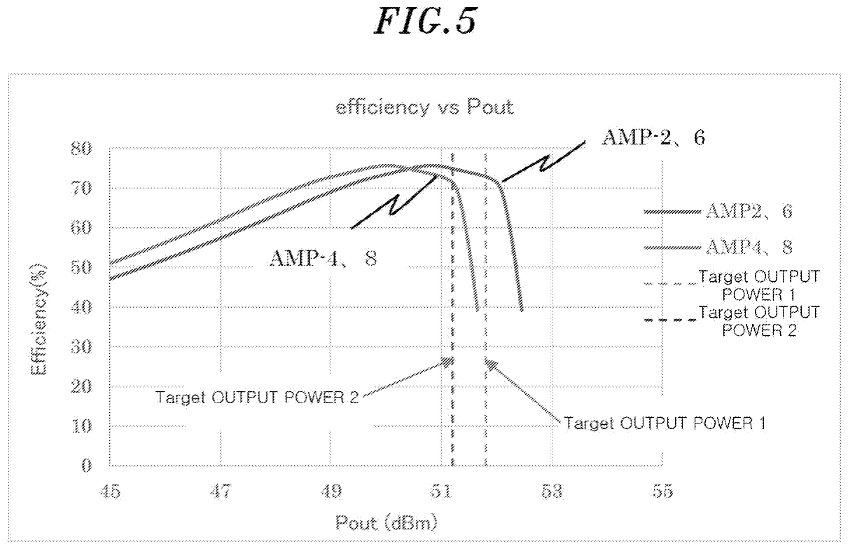

In FIGS. 4A to 4C, an example of a simulation result of RF characteristics is shown when the MOS-FET performs Class B operation. FIGS. 4A and 4B show a gain (dB) and efficiency (%), respectively, the efficiency of the MOS-FET is increasing as output power increases during Class B operation, and efficiency thereof around P2dB (2dB gain compression point) has a highest efficiency point of 75.6% which is maximum efficiency. However, when the output power increases further, it can be seen that the efficiency of the MOS-FET decreases conversely.

The reason for the above phenomenon is estimated that, although the current consumption of each of the AMP-4 and the AMP-8 of the present power amplifier is higher than that of each of the remaining AMPS, since the saturated power of the MOS-FET of each of the AMP-4 and the AMP-8 is lower than that of each of the remaining AMPS as illustrated in FIG. 4C, in a state in which the AMPS are included in the device, the AMPS are operated with output power of which the efficiency is higher than that of the highest point and thus are operated in a state in which the efficiency is decreased. Accordingly, in the power amplifier in which the plurality of AMPS are combined, when the AMP having a low saturated power is operated at an output power level at which the efficiency is greater than that of the highest point, it may be considered that the efficiency of the device is adversely affected.

On the basis of the above-described consideration result of the present inventor, an embodiment of a power amplifier capable of improving the device efficiency of the power amplifier, in which the AMPS are combined, by adjusting a gate voltage of each of the MOS-FETs of the AMPS on the basis of the saturated power will be described.

### First Embodiment

A first embodiment is an embodiment of a power amplifier which combines the output power of a plurality of AMPS and has a configuration for controlling output power ratios of the plurality of AMPS on the basis of individual differences in saturated power between the plurality of AMPS. That is, the first embodiment is an embodiment of a power amplifier which combines the output power of AMPS including a plurality of FETs disposed in parallel, individually adjusts gate voltages of the FETs on the basis of individual differences in saturated power between the plurality of FETs, decreases an output power ratio of an FET having low saturated power, and increases an output power ratio of an FET having high saturated power.

More specifically, the first embodiment is an embodiment of a power amplifier in which eight AMPS are combined as shown in FIG. 1, and the used AMP is set so that a gate voltage Vg is about 2.0 V during Class AB operation and is about 1.5 V during Class B operation. In this case, since there are individual differences in saturated power between the eight AMPS as described above, in the present embodiment, the gate voltage Vg is adjusted as follows. Accordingly, the output power ratio of the AMP having the low saturated power may be decreased, and the output power ratio of the AMP having the high saturated power may be increased.

The AMP having low saturated power: the gate voltage Vg is decreased by 0.1 V.

The AMP having high saturated power: the gate voltage Vg is increased by 0.1 V.

In this adjustment, the output power of the AMP having the high saturated power is increased by increasing the gate voltage Vg, and output power of the AMP having the low saturated power is decreased by decreasing the gate voltage Vg. Table 2 shows the device efficiency and current consumption of the AMPS when the gate voltage Vg of each of the eight MOS-FETs is adjusted according to the present embodiment. The AMP-1 and the AMP-5 are not adjusted, and the gate voltage Vg is 1.5 V. When compared to Table 1, the device efficiency is improved by 0.3%.

TABLE 2

| | | | | | | | | | Current |
|---|---|---|---|---|---|---|---|---|---|
| Device | | | | | | | | | Consumption |
| Efficiency | AMP-1 | AMP-2 | AMP-3 | AMP-4 | AMP-5 | AMP-6 | AMP-7 | AMP-8 | (Sum) |
| (%) | (A) | (A) | (A) | (A) | (A) | (A) | (A) | (A) | (A) |
| 61.0 | 15.3 | 14.7 | 14.9 | 15.4 | 15.1 | 14.4 | 14.8 | 16.0 | 120.5 |
| Vg | 1.5 V | 1.5 V-1.6 V | 1.5 V-1.6 V | 1.5 V-1.4 V | 1.5 V | 1.5 V-1.6 V | 1.5 V-1.6 V | 1.5 V-1.4 V | |
| Adjustment | (No | | | | (No | | | | |
| | Adjustment) | | | | Adjustment) | | | | |

FIG. 5 is a graph for describing an adjustment content of the power amplifier according to the present embodiment. As shown in FIG. 5, in the power amplifier of the present embodiment, two target output powers are set, each of the AMP-2 and the AMP-6 is set to the target output power 1 to have an output power higher than that of each of the remaining AMPS to cover the output power of each of the remaining AMPS. Meanwhile, each of the AMP-4 and the AMP-8 is set to the target output power 2 to have an output power lower than that of each of the remining AMPS to avoid operating at an inefficient output power level.

When the gate voltage Vg of each of the AMPS is adjusted according to the present embodiment, the device efficiency is improved by 0.3% by changing from 60.7% to 61.0%.

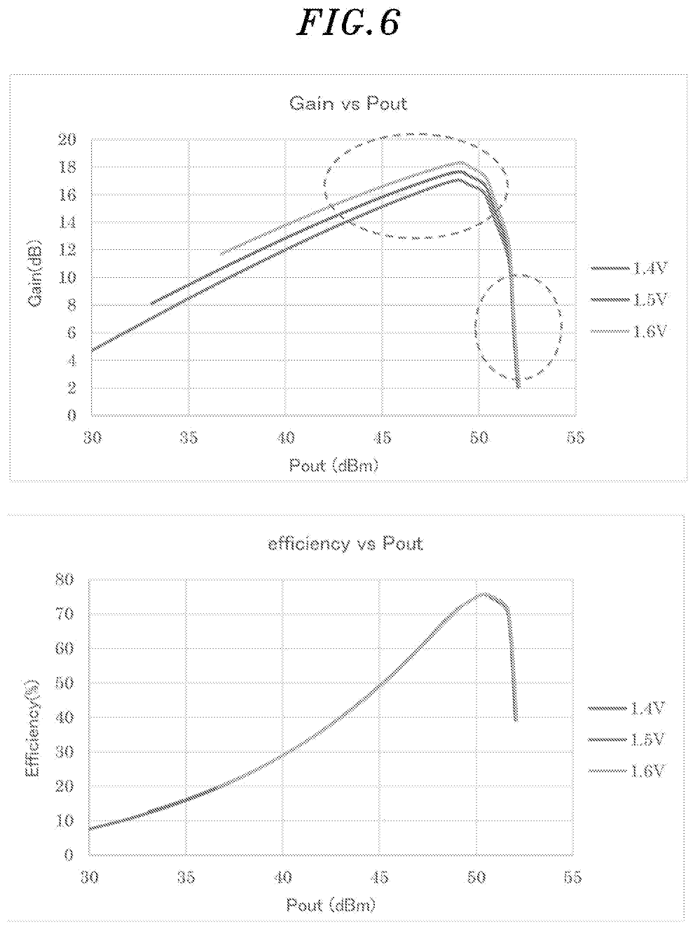

In addition, FIG. 6, which is a reference view, shows characteristics when the gate voltage Vg of the Class B AMP is adjusted ±0.1 V from 1.5 V. As shown in an upper graph of FIG. 6, although the gain is increased when the gate voltage Vg is increased, the saturated power is not changed even when the gate voltage Vg is increased. Meanwhile, as shown in a lower graph, it can be seen that the efficiency is not changed even when the gate voltage Vg is changed. Accordingly, the effectiveness of the present embodiment, in which the saturated power and the efficiency are not affected even when the gate voltage Vg is changed, is shown.

The present invention is not limited to the above-described embodiment, and includes various modifications. For example, the above-described embodiment has been described in detail for the sake of preferable understanding of the present invention, and the present invention is not necessarily limited to including all of the components described above. For example, the intermediate power AMP may not be present, and all of the plurality of AMPS may also be disposed not to be parallel.

In addition, in the present specification, various inventions in addition to the invention described in the claims are disclosed. Examples thereof will be described as follows.

<Enumeration 1>

A method of driving a power amplifier, in which output power of a plurality of amplifier circuits are combined, includes controlling output power ratios of the plurality of AMPS on the basis of individual differences in saturated power between the plurality of AMPS.

<Enumeration 2>

The method of driving the power amplifier described in Enumeration 1 includes decreasing an output power ratio of an amplifier circuit having low saturated power among the plurality of AMPS.

<Enumeration 3>

The method of driving the power amplifier described in Enumeration 2 includes increasing an output power ratio of an amplifier circuit having high saturated power among the plurality of AMPS.

<Enumeration 4>

The method of driving the power amplifier described in Enumeration 3 includes individually adjusting gate voltages of FETs included in the amplifier circuits on the basis of the individual differences in saturated power between a plurality of FETs to control output power ratios of the FETs.

### DESCRIPTION OF REFERENCE NUMERALS

11: gain block

12: intermediate power AMP

13: distributor

14: AMP

15: synthesizer

1. A power amplifier, which combines output power of a plurality of amplifier circuits, for controlling output power ratios of the plurality of amplifier circuits on the basis of individual differences in saturated power between the plurality of amplifier circuits,
wherein an output power ratio of an amplifier circuit having low saturated power is decreased among the plurality of amplifier circuits.

2. The power amplifier of claim 1, wherein an output power ratio of an amplifier circuit having high saturated power is increased among the plurality of amplifier circuits.

3. The power amplifier of claim 2, wherein the plurality of amplifier circuits are disposed in parallel.

4. The power amplifier of claim 3, wherein:
the amplifier circuits include a plurality of field-effect transistors (FETs); and
output power ratios of the FETs are controlled by individually adjusting gate voltages of the FETs on the basis of individual differences in saturated power between the plurality of FETs.

5. (canceled)
